(19) United States
(12) Patent Application Publication
(10) Pub. No.: US 2011/0118999 A1
(43) Pub. Date: May 19, 2011

(54) MEASUREMENT POSITION AND TIME RECORDING TYPE MAGNETOMETER AND METHOD OF MEASURING MAGNETIC FIELD USING THE SAME

(76) Inventors: Tae Kyu Lee, Seoul (KR); Jae Joon Kim, Seoul (KR); Yun Seok Lim, Dejeon (KR); Yoon Myoung Gimm, Seoul (KR)

(21) Appl. No.: 12/674,899

(22) PCT Filed: Aug. 23, 2007
(86) PCT No.: PCT/KR07/04044

§ 371 Date: Feb. 23, 2010

(51) Int. Cl. G06F 19/00; G01R 33/00; G06F 17/40

(52) U.S. Cl. 702/57; 702/187

(57) ABSTRACT

Disclosed herein are a magnetometer which is capable of calculating an isotropic magnetic field component by use of three orthogonal coil sensors for magnetic field measurement and a method for measuring a magnetic field using the magnetometer, which records and displays the strength and/or direction of the magnetic field together with the measurement time and position of the magnetic field. The magnetometer can make a more comprehensive understanding of a magnetic field environment and to make a more accurate measurement of a magnetic field. In addition, the magnetometer can reduce time for measurement and result analysis, and obtain reliable measurement results.

### TECHNICAL FIELD

The present invention relates to a magnetometer capable of calculating an isotropic magnetic field component by use of three orthogonal coil sensors for magnetic field measurement and a method for measuring a magnetic field using the magnetometer, which records and displays the strength and/or direction of the magnetic field together with the measurement time and position of the magnetic field.

### BACKGROUND ART

A magnetic field is a solenoidal vector field in the space surrounding moving electric charges and magnetic dipoles, such as those in electric currents and magnets. In general, magnetic fields are produced from nearly all electrical or electronic equipment and facilities ranging from high-voltage power lines to household electric appliances. Many studies on exposure to magnetic fields have raised serious concerns about the potential harmful effects thereof.

Accordingly, guidelines on a limit of exposure to magnetic fields produced from electrical or electronic equipment and facilities have been established, and various magnetometers have been developed and used to make an accurate measurement of magnetic fields.

A magnetic field is a vector field in a three-dimensional space, which is typically measured by measuring its three axial components using a three-axis magnetometer equipped with three orthogonal coil sensors, i.e. X-, Y- and Z-axis coil sensors, followed by calculating an isotropic magnetic field component from the three axial components.

Comprehensive understanding of a magnetic field environment and accurate measurement of exposure to a magnetic field will require extensive experiments over wide areas at different periods of time. Since conventional magnetometers have a simple function of recording and displaying the strength and/or direction of a magnetic field, it requires an additional operation to record the measurement time and position, and complex post-processing to obtain accurate measurement results. Hence, it takes long time to measure magnetic fields and to analyze the measurement results. Furthermore, since these measurement results are not based on information of the measurement time and position, the conventional magnetometers have a problem of a low reliability.

### DISCLOSURE OF INVENTION

### Technical Problem

The present invention is conceived to solve the problems of the conventional techniques as described above, and an aspect of the present invention is to provide a three-axis magnetometer capable of storing measurement time and position information of a magnetic field, together with the strength and/or direction of the magnetic field, from a real time clock (RTC) and a global positioning system (GPS), respectively, which are connected to a central processing unit (CPU) of the magnetometer.

It is another aspect of the present invention to provide a simplified three-axis magnetometer that can make a magnetic-field measurement in a time-sharing manner using an amplifier and a converter by controlling a multiplexer, which is connected to three orthogonal coil sensors, with the CPU. It is a further aspect of the present invention to provide a three-axis magnetometer that has an extended measurement range through gain adjustment of an amplifier.

### Technical Solution

In accordance with an aspect of the present invention, the above and other features of the present invention can be accomplished by the provision of a measurement position and time recording type magnetometer including three orthogonal coil sensors, an amplifier connected to the three orthogonal coil sensors to amplify analog signals, an analog-to-digital (AD) converter to convert the amplified analog signals to digital signals and to input the digital signals to a central processing unit (CPU), and a memory unit to store the digital signals, wherein a real time clock (RTC) is connected to the CPU to input measurement time information to the CPU, a global positioning system (GPS) module is connected to the CPU to input measurement position information to the CPU, and the memory unit stores the measurement time and position information together with measurement values of the signals.

The three orthogonal coil sensors may be connected to the amplifier through filters, attenuators and a multiplexer, and the CPU may control the multiplexer to make a measurement in a time-sharing manner through alternative connection of the respective coil sensors to the amplifier.

The CPU may be connected to the amplifier and adjust gain of the amplifier to control a magnetic field measurement range.

In accordance with another aspect of the present invention, a method for measuring a magnetic field using the measurement position and time recording type magnetometer of the present invention, including: storing target positions in the memory unit; reading and inputting GPS coordinates of a current measurement position to a CPU; calculating a distance between the current measurement position and one of the target positions nearest to the current measurement position; determining whether or not the calculated distance falls within a predetermined tolerance; and measuring a magnetic field component at each of the three orthogonal coil sensors while storing the GPS coordinates, current time, and a measurement value of the magnetic field component in the memory unit, in response to an input signal indicating that the calculated distance falls within the predetermined tolerance.

### Advantageous Effects

As apparent from the above description, it is possible to make a more comprehensive understanding of a magnetic field environment and to make a more accurate measurement of a magnetic field. In addition, it is possible to reduce time for measurement and result analysis and to obtain reliable measurement results.

### BRIEF DESCRIPTION OF THE DRAWINGS

FIG. 1 is a perspective view of a magnetometer according to an exemplary embodiment of the present invention;

FIG. 2 is a block diagram of the magnetometer according to the exemplary embodiment of the present invention;

FIG. 3 is a flow chart of a method for operating a magnetometer according to an exemplary embodiment of the present invention;

FIG. 4 illustrates a display unit according to an exemplary embodiment of the present invention; and

FIG. 5 is a flow chart of a method for measuring and recording a magnetic field at a target point according to an exemplary embodiment of the present invention.

### BEST MODE FOR CARRYING OUT THE INVENTION

Exemplary embodiments of the present invention will be described in detail with reference to the accompanying drawings hereinafter.

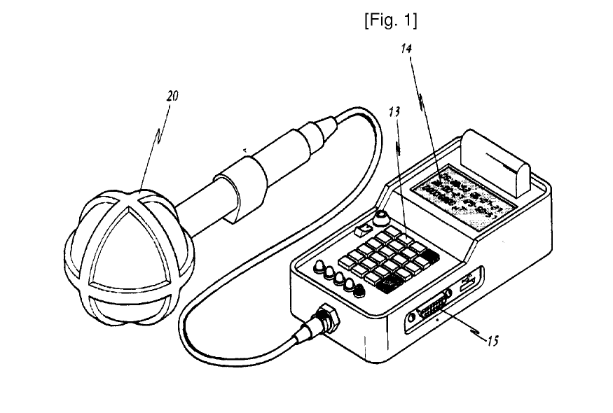

FIG. 1 is a perspective view of a magnetometer according to an embodiment of the present invention. The magnetometer includes a sensing unit 20 equipped with three orthogonal coil sensors, an input key 13, a display unit 14, and a communication port 15. The sensing unit 20 may be separated from a main body as shown in FIG. 1, or may be incorporated into the main body.

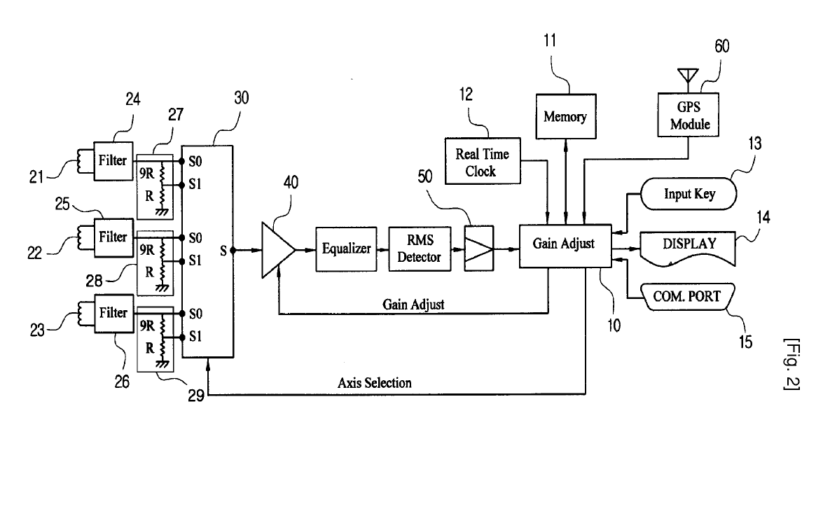

FIG. 2 is a block diagram of the magnetometer according to the embodiment of the present invention. The magnetometer includes X-, Y- and Z-axis coil sensors 21, 22 and 23, filters 24, 25 and 26, attenuators 27, 28 and 29, a multiplexer 30, a central processing unit (CPU) 10, an amplifier 40, and an AD converter 50. The X-, Y- and Z-axis coil sensors 21, 22 and 23 are connected to the multiplexer 30, which is controlled by the CPU 10, through the filters 24, 25 and 26 and the attenuators 27, 28 and 29. Analog signals sensed by the coil sensors 21, 22 and 23 are transmitted to the multiplexer 30 through the filters 24, 25 and 26 and the attenuators 27, 28 and 29, amplified by the amplifier 40, converted to digital signals by the AD converter 50, and are finally input to the CPU 10.

The CPU 10 is also connected to the input key 13, the display unit 14, the communication port 15, a memory unit 11, a real time clock (RTC) 12, and a global positioning system (GPS) module 60. The input key 13 is used to input instructions for operation. The display unit 14 displays operation states, strength and/or direction of a magnetic field, measurement position, and measurement time. The communication port 15 communicates with external devices such as computers. The memory unit 11 records various types of data, such as the strength and/or direction of the magnetic field. The RTC 12 notifies the CPU 10 of current time. The GPS module 60 notifies the CPU 10 of the coordinate and altitude of a measurement point.

The magnetometer may further include an equalizer and a root mean square (RMS) detector. The equalizer is connected to the multiplexer 30 to correct and equalize a variation of a signal during transmitting and sensing the signal. The RMS detector detects RMS values prior to conversion of the signal to a digital signal.

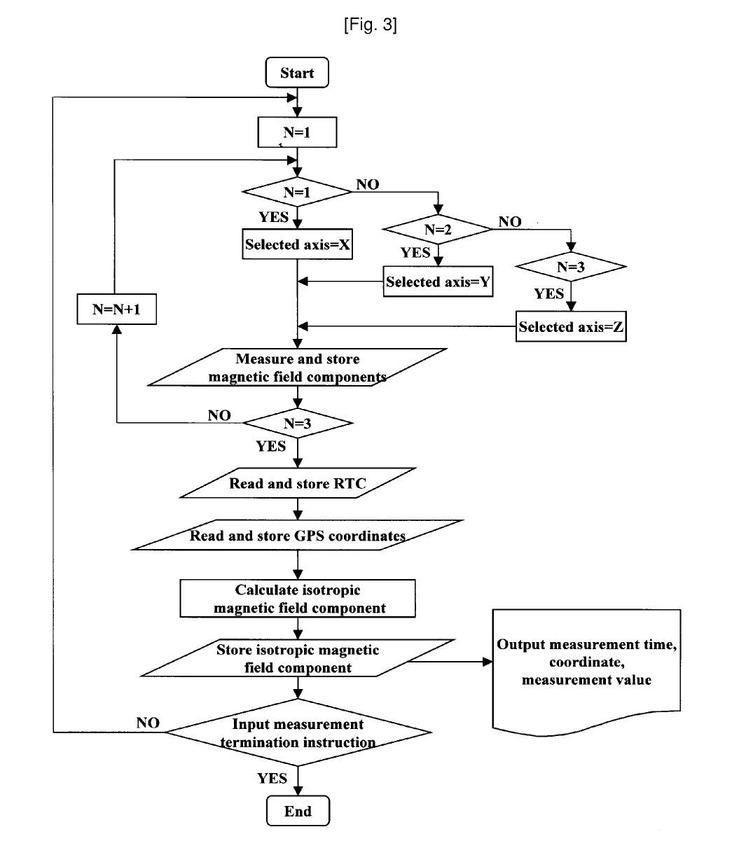

FIG. 3 is a flow chart of a method for operating a magnetometer according to an embodiment of the present invention. In more detail, FIG. 3 shows a method for operating a magnetometer shown in FIG. 2 to measure and record a magnetic field together with the measurement time and position of the magnetic field.

As shown in FIG. 3, the CPU 10 controls the multiplexer 30 to connect each coil sensor in sequence to the subsequent circuit.

That is, the X-axis coil sensor 21, the Y-axis coil sensor 22, and the Z-axis coil sensor 23 are connected sequentially and alternatively to the subsequent circuit to measure magnetic field components in a time-sharing manner. Accordingly, the three coil sensors are treated as if simultaneously operated.

The magnetic field components at the respective axes are stored in the memory unit 11 and, at the same time, the CPU 10 receives measurement time information and measurement position information from the RTC 12 and the GPS module 60, respectively, and stores the information in the memory unit 11.

The GPS module 60 detects a GPS signal and measures the latitude, longitude and altitude of a detected point from the GPS signal. If the GPS simply includes a GPS antenna and its accessories, the CPU 10 may make a calculation of position information. Alternatively, if the GPS module 60 is a typical commercial GPS receiver, the GPS module 60 may input the position information to the CPU 10. These operations can be easily practiced by those skilled in the art and thus is not be specifically defined in the accompanying claims.

After the measurement time and position information is stored, the CPU 10 extracts the magnetic field components from the memory unit 11, squares the respective magnetic field components, obtains the sum of the squared values, and obtains the square root of the sum of the squared values, thereby providing an isotropic magnetic field component that is a vector sum of magnetic field components of the respective axes. The isotropic magnetic field component is also stored in the memory unit 11.

The aforementioned magnetic field measurement is repeatedly performed until its termination instruction is input through the input key 13. Then, the values of the magnetic field, and measurement time and position information will be stored in the form of a database in the memory unit 11.

The measurement values and the measurement time and position information are stored in the memory unit 11 and are output to the display unit 14 so that the user can read them. Additionally, the measurement values and the measurement time and position information can be transmitted to an external computer through the communication port 15.

The amplifier 40 is connected to the CPU 10. The gain of the amplifier is adjusted by the CPU 10, adjusting a measurable range of the magnetic field to obtain a dynamic range.

If a magnetic field strength ranges from 0.01 to 1.00 mT, the CPU 10 selects terminals S0, S2 and S4 of the multiplexer to control the amplifier 40 to have a high gain. If a magnetic field strength ranges from 1.00 to 10.0 mT, the CPU 10 selects terminals S0, S2 and S4 of the multiplexer to control the amplifier 40 to have a low gain. If a magnetic field strength ranges from 10.0 to 100.0 mT, the CPU 10 selects terminals S1, S3 and S5 of the multiplexer to control the amplifier 40 to have a low gain.

Hence, it is possible to obtain a linear circuit from the aforementioned analog gains that depend on the magnetic field strengths.

According to the present invention, the memory unit 11 may store a plurality of target measurement points or target measurement areas, and, the measurement can be made along a path consisting of the target measurement points while making an automatic record of measurement information.

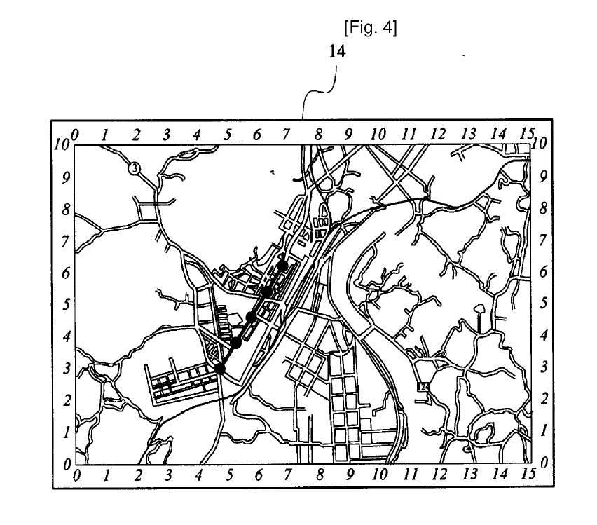

In more detail, as shown in FIG. 4, when the display unit 14 displays a digital map from the GPS module 60, the user inputs target positions by use of the input key 13. If the user moves along a path consisting of the target positions to make a measurement, the CPU 10 automatically records the magnetic field values and the measurement time using GPS coordinates upon approaching the target positions.

As a result, it is not necessary to try to find the target positions at actual sites, or not necessary to perform an extra operation to extract only a measurement value at a specific coordinate.

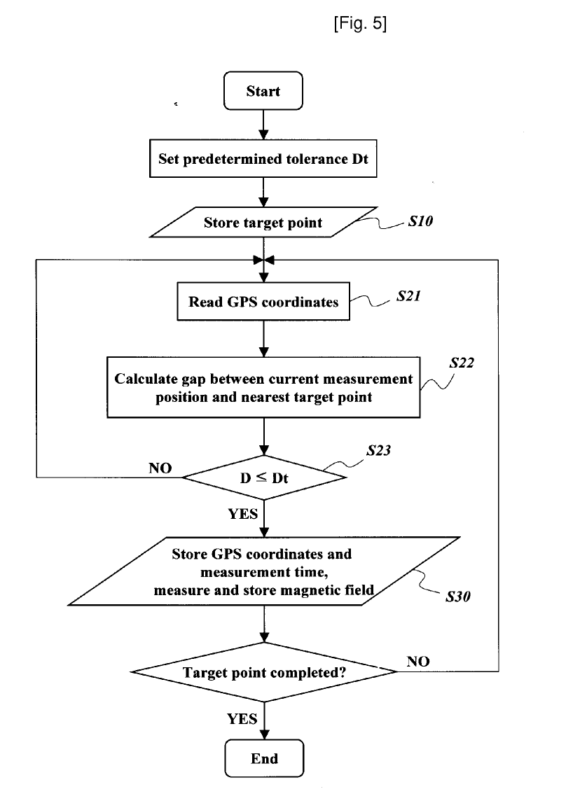

FIG. 5 is a flow chart of a process for tracking target measurement points according to an exemplary embodiment of the present invention. As shown in FIG. 5, the magnetometer of the invention continues to receive GPS coordinates during motion, calculates a gap between a current point and one of the target positions nearest to the current point, and, if the gap falls within a predetermined tolerance, records the GPS coordinates, measurement time and magnetic field component for each axis.

If there is a plurality of measurement points falling within a predetermined tolerance with respect to one target point, one of the measurement points nearest to the target point is selected and measured. The selection of the measurement point may be made by an extra operation during the measurement, or may be made by post-processing data from the memory unit after the measurement is completed. This can be easily done by those skilled in the art and is thus not specifically defined in the accompanying claims.

Further, the target positions may have specific coordinate values or specific areas. The target positions may be input through the input key 13, or through an external device, such as a computer, which is connected through the communication port 15.

Accordingly, the present invention provides a measurement position and time recording type magnetometer including three orthogonal coil sensors 21, 22 and 23, an amplifier 40 connected to the three orthogonal coil sensors to amplify analog signals, an AD converter 50 to convert the amplified analog signals to digital signals and to input the digital signals to a CPU 10, and a memory unit 11 to store the digital signals, wherein an RTC 12 is connected to the CPU 10 to input measurement time information to the CPU 10, a GPS module 60 is connected to the CPU 10 to input measurement position information to the CPU 10, and the memory unit 11 stores the measurement time and position information together with measurement values of the signals. In this case, the three orthogonal coil sensors 21, 22 and 23 are connected to the amplifier 40 through a multiplexer 30 via filters 24, 25 and 26 and attenuators 27, 28 and 19, and the CPU 10 controls the multiplexer 30 to allow the respective coil sensors to make a measurement in a time-sharing manner through alternative connection to the amplifier 40. Further, the CPU 10 is connected to the amplifier 40 and regulates gain of the amplifier 40 to control a magnetic field measurement range.

In addition, the present invention provides a method for measuring a magnetic field using the aforementioned measurement position and time recording type magnetometer, including: storing target positions in the memory unit 11 (S10); reading and inputting GPS coordinates of a current measurement position to the CPU 10 (S21); calculating a distance between the current measurement position and one of the target positions nearest to the current measurement position (S22); determining whether or not the calculated distance falls within a predetermined tolerance by the CPU 10 (S23); and measuring a magnetic field component at each of the three orthogonal coil sensors while storing the GPS coordinates, current time, and a measurement value of the magnetic field component in the memory unit 11 (S30), if it is determined at the operation S23 that the calculated distance falls within the predetermined tolerance. Here, the measuring operation (S30) includes controlling the amplifier 40 to have a high gain by selecting terminals S0, S2 and S4 in the multiplexer if the measurement value of the magnetic field component has a magnetic field strength ranging from 0.01 to 1.00 mT; controlling the amplifier 40 to have a first low gain by selecting terminals S0, S2 and S4 in the multiplexer if the measurement value of magnetic field component has a magnetic field strength ranging from 1.00 to 10.0 mT; and controlling the amplifier 40 to have a second low gain by selecting terminals S1, S3 and S5 in the multiplexer if the measurement value of magnetic field component has a magnetic field strength ranging from 10.0 to 100.0 mT, to obtain a linearized circuit.

1. A measurement position and time recording type magnetometer comprising:
three orthogonal coil sensors,
an amplifier connected to the three orthogonal coil sensors to amplify analog signals,
an analog-to-digital (AD) converter to convert the amplified analog signals to digital signals and to input the digital signals to a central processing unit (CPU), and
a memory unit to store the digital signals,
wherein a real time clock (RTC) is connected to the CPU to input measurement time information to the CPU, a global positioning system (GPS) module is connected to the CPU to input measurement position information to the CPU, and the memory unit stores the measurement time and position information together with measurement values of the signals.

2. The magnetometer according to claim 1, wherein the three orthogonal coil sensors are connected to the amplifier through a multiplexer via filters and attenuators, and the CPU controls the multiplexer to allow the respective coil sensors to make a measurement in a time-sharing manner through alternative connection to the amplifier.

3. The magnetometer according to claim 1, wherein the CPU is connected to the amplifier and adjusts gain of the amplifier to control a magnetic field measurement range.

4. A method for measuring a magnetic field using the measurement position and time recording type magnetometer that includes three orthogonal coil sensors, an amplifier connected to the three orthogonal coils sensors to amplify analog signals to digital signals, an analog-to-digital (AD) converter to convert the amplified analog signals to digital signals and to input the digital signals to a central processing unit (CPU), and a memory unit to store the digital signals, wherein a real time clock (RTC) is connected to the CPU to input measurement time information to the CPU, a global positioning system (GPS) module is connected to the CPU to input measurement position information to the CPU, and the memory unit stores the measurement time and position information together with measurement values of the signal, the method comprising:
storing target positions in the memory unit;
reading and inputting GPS coordinates of a current measurement position to the CPU;
calculating a distance between the current measurement position and one of the target positions nearest to the current measurement position by the CPU;
determining whether or not the calculated distance falls within a predetermined tolerance by the CPU; and
measuring a magnetic field component at each of the three orthogonal coil sensors while storing the GPS coordinates, current time, and a measurement value of the magnetic field component in the memory unit, in response to an input signal indicating that the calculated distance falls within the predetermined tolerance.

5. The method according to claim 4, wherein the measuring step comprises:
controlling the amplifier to have a high gain by selecting a first set of terminals in the multiplexer if the measurement value of the magnetic field component has a magnetic field strength ranging from 0.01 to 1.00 mT;
controlling the amplifier to have a first low gain by selecting the first set of terminals in the multiplexer if the measurement value of the magnetic field component has a magnetic field strength ranging from 1.00 to 10.0 mT; and
controlling the amplifier to have a second low gain by selecting a second set of terminals in the multiplexer if the measurement value of magnetic field component has a magnetic field strength ranging from 10.0 to 100.0 mT, to obtain a linearized circuit.
